(19) United States
(12) Patent Application Publication
(10) Pub. No.: US 2025/0343394 A1
(43) Pub. Date: Nov. 6, 2025

(54) Distributed Feedback (DFB) Interband Cascade Lasers With Hybrid Cladding Layers

(71) Applicant: The Board of Regents of the University of Oklahoma, Norman, OK (US)

(72) Inventor: Rui Q. Yang, Norman, OK (US)

(21) Appl. No.: 19/200,267

(22) Filed: May 6, 2025

Related U.S. Application Data
(60) Provisional application No. 63/642,971, filed on May 6, 2024.

(51) Int. Cl. H01S 5/34; H01S 5/125; H01S 5/22; H01S 5/223; H01S 5/30

(52) U.S. Cl. CPC H01S 5/3402; H01S 5/125; H01S 5/2206; H01S 5/223; H01S 5/305

(57) ABSTRACT

A semiconductor distributed feedback (DFB) interband cascade (IC) laser (ICL) comprises (1) an IC region having an IC region real refractive index, the IC region configured to generate light based on interband transitions; (2) an outer cladding layer formed from a high-doped semiconductor material and having an outer cladding layer real refractive index which is lower than the IC region real refractive index; (3) an inner cladding layer having an inner cladding layer real refractive index which is lower than the IC region real refractive index; and (4) a DFB grating formed in the outer cladding region for achieving single-mode emission. The semiconductor DFB ICL may further include at least one separate confinement layer (SCL) positioned between the IC region and the inner cladding layer. The semiconductor DFB ICL may comprise an outer cladding layer positioned on a GaSb substrate. The ICL may comprise a semi-insulating substrate.

### CROSS-REFERENCE TO RELATED APPLICATIONS

This claims priority to U.S. Provisional Application No. 63/642,971, filed on May 6, 2024, which is expressly incorporated herein by reference in its entirety.

### STATEMENT REGARDING FEDERALLY SPONSORED RESEARCH OR DEVELOPMENT

This invention was made with government support under NSF (ECCS-1931193) awarded by the National Science Foundation. The government has certain rights in the invention.

### BACKGROUND

In about three decades since the original proposal of the interband cascade laser (ICL), a multitude of developments has paved the way for this III-V based technology to produce efficient and coherent mid-infrared (IR) sources. Operating in a wide range of wavelengths from below 3 μm to above 14 μm, ICLs based on the type-II quantum well (QW) active region have stimulated many technological applications including chemical sensing, medical diagnoses, free-space communication, imaging, and industrial process control.

Currently, the majority of ICLs use short period InAs/AlSb superlattice (SL) cladding layers. However, the SL cladding has a low thermal conductivity, resulting in poor thermal dissipation. Additionally, ICLs with thick SL cladding layers are not compatible with making the single-mode distributed feedback (DFB) lasers with the top DFB grating configuration. Due to the stack of two different semiconductor materials, the etching through the SL cladding is not easy with a desirable shape, which affects the quality of DFB grating. Single-mode DFB ICLs are required for many applications such as chemical sensing, environmental and greenhouse gas monitoring, detection of gas leaks, food safety, and medical diagnoses. It is therefore desirable to improve on such single-mode DFB ICLs.

### BRIEF DESCRIPTION OF THE DRAWINGS

For a more complete understanding of this disclosure, reference is now made to the following brief description, taken in connection with the accompanying drawings and detailed description, wherein like reference numerals represent like parts.

FIG. 1 is a schematic diagram of the overall structure showing the various segments and the interband cascade region, including thin connection regions (hatched) between them.

FIG. 2 is a schematic side view of a layer structure along the longitudinal direction showing the formation of a DFB grating with a depth of d and a period of p.

FIG. 3 is a schematic side view of a layer structure along the longitudinal direction showing the formation of a DFB grating with a period of p, where its voids are filled by dielectric material.

FIG. 4 is a schematic band diagram and layer structure of an interband cascade stage, where the thickness (in unit of Å) of each layer in one stage beginning at the barrier separating the electron injector and the active region is 25, 16.5, 28, 14, 12, 32, 12, 48, 21, 41, 12, 33, 12, 27, 12, 22, 12, 19, 12 and 16.5.

FIG. 5 is a schematic cross-sectional view of a layer structure along the lateral direction showing the arrangement of metal contacts.

FIG. 6 is a schematic illustration of the overall ICL structure on a semi-insulating substrate including the arrangement of metal contacts.

### ABBREVIATIONS

Å: angstrom(s)
AlGaInSb: aluminum gallium indium antimonide
AlGaInSbAs: aluminum gallium indium antimony arsenide
AlGaSbAs: aluminum gallium antimony arsenide
AlSb: aluminum antimonide
AlSbAs: aluminum antimony arsenide
BA: broad area
cm⁻³: inverse cubic centimeters
cw: continuous wave
DFB: distributed feedback
GaAs: gallium arsenide
GaInSb: gallium indium antimonide
GaSb: gallium antimonide
IC: interband cascade
ICL: interband cascade laser
InAs: indium arsenide
InAsSb: indium arsenic antimonide
InGaAsSb: indium gallium arsenic antimonide
InP: indium phosphide
IR: infrared
K: degrees Kelvin
MBE: molecular beam epitaxy
mm: millimeter(s)
nm: nanometer(s)
NSF: National Science Foundation
QW: quantum well
SCL: separate confinement layer
Si: silicon
Si₃N₄: silicon nitride
SiO₂: silicon dioxide
SL: superlattice
T: temperature
Te: Tellurium
Å: angstrom(s)
μm: micrometer(s)

### DETAILED DESCRIPTION

Disclosed herein are ICLs with an advanced waveguide structure comprising hybrid cladding layers, which will facilitate the fabrication of single-mode DFB lasers and result in improved device performance in terms of enhanced thermal dissipation and low threshold current density. The disclosed ICL includes a waveguide core comprising an active interband cascade region, wherein the active region is configured to generate light based on interband transitions. The ICLs use a highly-doped semiconductor layer as the outer cladding layer and are grown upon a GaSb substrate or an InAs substrate. The ICLs can be grown on a semi-insulating substrate such as a Si substrate, but with a metal contact on the highly-doped semiconductor bottom cladding layer. As such, the threshold voltage and operating voltage of the ICL are reduced with improved voltage efficiency.

Before further describing various embodiments of the apparatus, component parts, and methods of the present disclosure in more detail by way of exemplary description, examples, and results, it is to be understood that the embodiments of the present disclosure are not limited in application to the details of apparatus, component parts, and methods as set forth in the following description. The embodiments of the apparatus, component parts, and methods of the present disclosure are capable of being practiced or carried out in various ways not explicitly described herein. As such, the language used herein is intended to be given the broadest possible scope and meaning; and the embodiments are meant to be exemplary, not exhaustive. Also, it is to be understood that the phraseology and terminology employed herein is for the purpose of description and should not be regarded as limiting unless otherwise indicated as so. Moreover, in the following detailed description, numerous specific details are set forth in order to provide a more thorough understanding of the disclosure. However, it will be apparent to a person having ordinary skill in the art that the embodiments of the present disclosure may be practiced without these specific details. In other instances, features which are well known to persons of ordinary skill in the art have not been described in detail to avoid unnecessary complication of the description. While the apparatus, component parts, and methods of the present disclosure have been described in terms of particular embodiments, it will be apparent to those of skill in the art that variations may be applied to the apparatus, component parts, and/or methods and in the steps or in the sequence of steps of the method described herein without departing from the concept, spirit, and scope of the inventive concepts as described herein. All such similar substitutes and modifications apparent to those having ordinary skill in the art are deemed to be within the spirit and scope of the inventive concepts as disclosed herein.

All patents, published patent applications, and non-patent publications referenced or mentioned in any portion of the present specification are indicative of the level of skill of those skilled in the art to which the present disclosure pertains, and are hereby expressly incorporated by reference in their entirety to the same extent as if the contents of each individual patent or publication was specifically and individually incorporated herein.

Unless otherwise defined herein, scientific and technical terms used in connection with the present disclosure shall have the meanings that are commonly understood by those having ordinary skill in the art. Further, unless otherwise required by context, singular terms shall include pluralities and plural terms shall include the singular.

As utilized in accordance with the methods and compositions of the present disclosure, the following terms and phrases, unless otherwise indicated, shall be understood to have the following meanings: The use of the word “a” or “an” when used in conjunction with the term “comprising” in the claims and/or the specification may mean “one,” but it is also consistent with the meaning of “one or more,” “at least one,” and “one or more than one.” The use of the term “or” in the claims is used to mean “and/or” unless explicitly indicated to refer to alternatives only or when the alternatives are mutually exclusive, although the disclosure supports a definition that refers to only alternatives and “and/or.” The use of the term “at least one” will be understood to include one as well as any quantity more than one, including but not limited to, 2, 3, 4, 5, 6, 7, 8, 9, 10, 15, 20, 30, 40, 50, 100, or any integer inclusive therein. The phrase “at least one” may extend up to 100 or 1000 or more, depending on the term to which it is attached; in addition, the quantities of 100/1000 are not to be considered limiting, as higher limits may also produce satisfactory results. In addition, the use of the term “at least one of X, Y and Z” will be understood to include X alone, Y alone, and Z alone, as well as any combination of X, Y and Z.

As used in this specification and claims, the words “comprising” (and any form of comprising, such as “comprise” and “comprises”), “having” (and any form of having, such as “have” and “has”), “including” (and any form of including, such as “includes” and “include”) or “containing” (and any form of containing, such as “contains” and “contain”) are inclusive or open-ended and do not exclude additional, unrecited elements or method steps.

The term “or combinations thereof” as used herein refers to all permutations and combinations of the listed items preceding the term. For example, “A, B, C, or combinations thereof” is intended to include at least one of: A, B, C, AB, AC, BC, or ABC, and if order is important in a particular context, also BA, CA, CB, CBA, BCA, ACB, BAC, or CAB. Continuing with this example, expressly included are combinations that contain repeats of one or more item or term, such as BB, AAA, AAB, BBC, AAABCCCC, CBBAAA, CABABB, and so forth. The skilled artisan will understand that typically there is no limit on the number of items or terms in any combination, unless otherwise apparent from the context.

Throughout this application, the terms “about” or “approximately” are used to indicate that a value includes the inherent variation of error for the apparatus, composition, or the methods or the variation that exists among the objects, or study subjects. As used herein the qualifiers “about” or “approximately” are intended to include not only the exact value, amount, degree, orientation, or other qualified characteristic or value, but are intended to include some slight variations due to measuring error, manufacturing tolerances, stress exerted on various parts or components, observer error, wear and tear, and combinations thereof, for example. The terms “about” or “approximately”, where used herein when referring to a measurable value such as an amount, percentage, temporal duration, and the like, is meant to encompass, for example, variations of ±20% or +10%, or ±5%, or +1%, or +0.1% from the specified value, as such variations are appropriate to perform the disclosed methods and as understood by persons having ordinary skill in the art. As used herein, the term “substantially” means that the subsequently described event or circumstance completely occurs or that the subsequently described event or circumstance occurs to a great extent or degree. For example, the term “substantially” means that the subsequently described event or circumstance occurs at least 90% of the time, or at least 95% of the time, or at least 98% of the time.

As used herein any reference to “one embodiment” or “an embodiment” means that a particular element, feature, structure, or characteristic described in connection with the embodiment is included in at least one embodiment. The appearances of the phrase “in one embodiment” in various places in the specification are not necessarily all referring to the same embodiment.

As used herein, all numerical values or ranges include fractions of the values and integers within such ranges and fractions of the integers within such ranges unless the context clearly indicates otherwise. Thus, to illustrate, reference to a numerical range, such as 1-10 includes 1, 2, 3, 4, 5, 6, 7, 8, 9, 10, as well as 1.1, 1.2, 1.3, 1.4, 1.5, etc., and so forth. Reference to a range of 1-50 therefore includes 1, 2, 3, 4, 5, 6, 7, 8, 9, 10, 11, 12, 13, 14, 15, 16, 17, 18, 19, 20, etc., up to and including 50, as well as 1.1, 1.2, 1.3, 1.4, 1.5, etc., 2.1, 2.2, 2.3, 2.4, 2.5, etc., and so forth. Reference to a series of ranges includes ranges which combine the values of the boundaries of different ranges within the series. Thus, to illustrate reference to a series of ranges, for example, a range of 1-1,000 includes, for example, 1-10, 10-20, 20-30, 30-40, 40-50, 50-60, 60-75, 75-100, 100-150, 150-200, 200-250, 250-300, 300-400, 400-500, 500-750, 750-1,000, and includes ranges of 1-20, 10-50, 50-100, 100-500, and 500-1,000. The range 100 units to 2000 units therefore refers to and includes all values or ranges of values of the units, and fractions of the values of the units and integers within said range, including for example, but not limited to 100 units to 1000 units, 100 units to 500 units, 200 units to 1000 units, 300 units to 1500 units, 400 units to 2000 units, 500 units to 2000 units, 500 units to 1000 units, 250 units to 1750 units, 250 units to 1200 units, 750 units to 2000 units, 150 units to 1500 units, 100 units to 1250 units, and 800 units to 1200 units. Any two values within the range of about 100 units to about 2000 units therefore can be used to set the lower and upper boundaries of a range in accordance with the embodiments of the present disclosure. More particularly, a range of 10-12 units includes, for example, 10, 10.1, 10.2, 10.3, 10.4, 10.5, 10.6, 10.7, 10.8, 10.9, 11.0, 11.1, 11.2, 11.3, 11.4, 11.5, 11.6, 11.7, 11.8, 11.9, and 12.0, and all values or ranges of values of the units, and fractions of the values of the units and integers within said range, and ranges which combine the values of the boundaries of different ranges within the series, e.g., 10.1 to 11.5.

As noted above, any numerical range listed or described herein is intended to include, implicitly or explicitly, any number or sub-range within the range, particularly all integers, including the end points, and is to be considered as having been so stated. For example, “a range from 1.0 to 10.0” is to be read as indicating each possible number, including integers and fractions, along the continuum between and including 1.0 and 10.0, that is, having a minimum value equal to or greater than 1.0 and a maximum value equal to or less than 10.0, such as, for example, 3.25 to 8.65. Any maximum numerical limitation recited herein is intended to include all lower numerical limitations subsumed therein, and any minimum numerical limitation recited in this specification is intended to include all higher numerical limitations subsumed therein. Accordingly, Applicant reserves the right to amend this specification, including the claims, to expressly recite any sub-range subsumed within the ranges expressly recited herein. Thus, even if a particular data point within the range is not explicitly identified or specifically referred to, it is to be understood that any data points within the range are to be considered to have been specified, and that the inventor(s) possessed knowledge of the entire range and the points within the range.

Where used herein, the pronoun “we” is intended to refer to all persons involved in a particular aspect of the investigation disclosed herein and as such may include non-inventor laboratory assistants and non-inventor collaborators working under the supervision of the inventor(s).

Where used herein, the term “real refractive index” of a material refers to the real part of refractive index of the material.

The present disclosure will now be discussed in terms of several specific, non-limiting, examples and embodiments. The examples described below, which include particular embodiments, will serve to illustrate the practice of the present disclosure, it being understood that the particulars shown are by way of example and for purposes of illustrative discussion of particular embodiments and are presented in the cause of providing what is believed to be a useful and readily understood description of procedures as well as of the principles and conceptual aspects of the present disclosure.

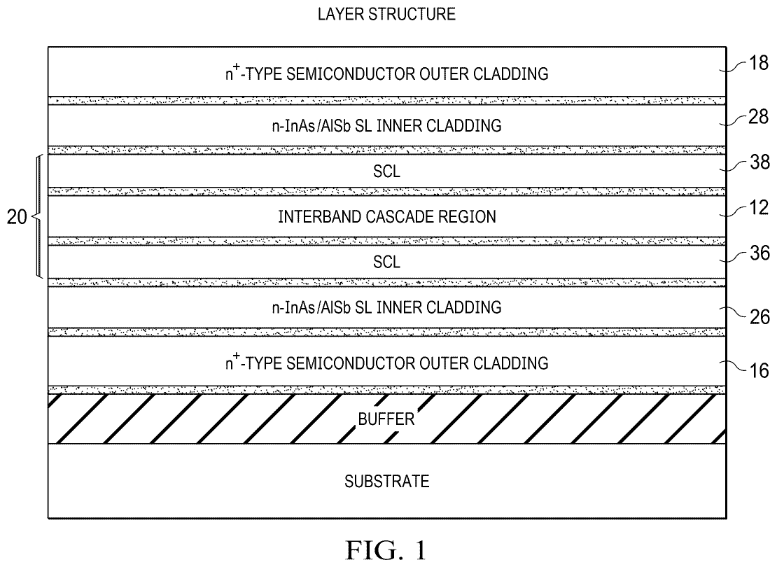

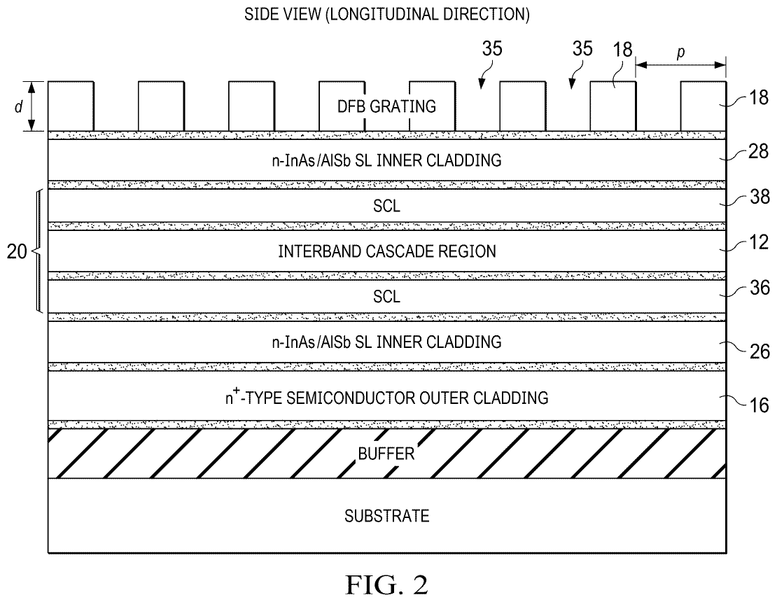

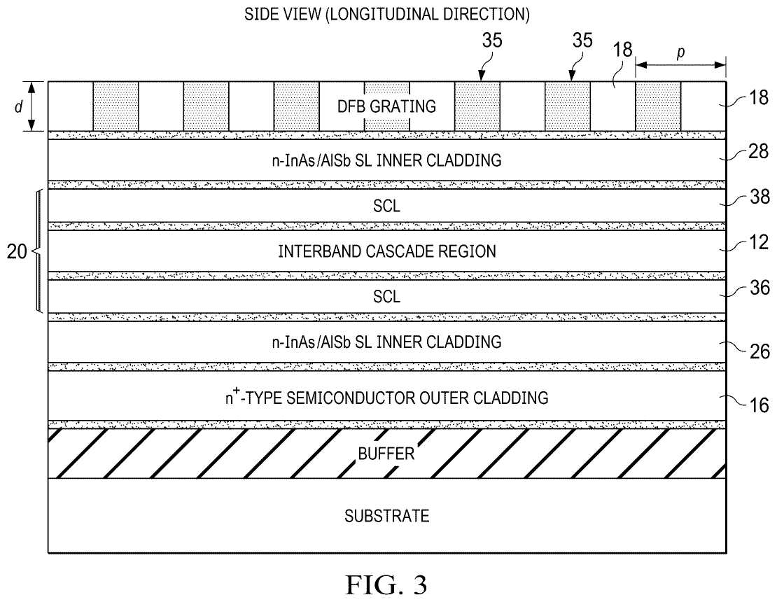

In a non-limiting example as shown in FIG. 1, the presently disclosed semiconductor ICL is constructed with (1) a waveguide core 20 comprising an active interband cascade region 12, which is sandwiched by the two SCLs 36 and 38; (2) two inner cladding layers 26 and 28 on the bottom and top of the waveguide core, respectively; and (3) two outer cladding layers 16 and 18, which are on the bottom of the inner cladding 26 and the top of the inner cladding 28, respectively. The SCLs 36 and 38 are made of GaSb for ICLs grown on GaSb substrates and are made of InAs for ICLs grown on InAs substrates. The outer semiconductor cladding 16 or 18 is formed from a high-doped semiconductor material having an outer cladding layer refractive index. It can be high doped n-type InAsSb lattice-matched to GaSb or n-type InAs. In a non-limiting example, “high-doped” means a doping concentration in a range of 5×10¹⁷ cm⁻³ to 5×10¹⁹ cm⁻³ depending on the lasing wavelength. The inner cladding layer 26 or 28 is formed from a semiconductor material having an inner cladding layer refractive index which is greater than the outer cladding layer refractive index. In FIG. 1, the inner cladding layer is formed by InAs/AlSb superlattice (SL), which can also be formed by an AlGaAsSb material. The active interband cascade region is configured to generate lasing light with emission wavelength λ based on interband transitions, wherein the active region refractive index is greater than the inner cladding layer refractive index. Additionally, the presently disclosed DFB ICL includes a DFB grating formed by etching with a depth d and a period p in the top outer cladding layer as shown in FIG. 2. The DFB grating period p is determined by p=λ/(2n_{eff}), where n_{eff} is an effective refractive index of the waveguide. The depth d should be chosen to make an appropriate coupling coefficient κ, for example, to make KL to be in the range of 1 to 2, where L is the laser length. The etched void 35 in the DFB grating can be filled by dielectric materials such as Si₃N₄ and SiO₂ as shown in FIG. 3.

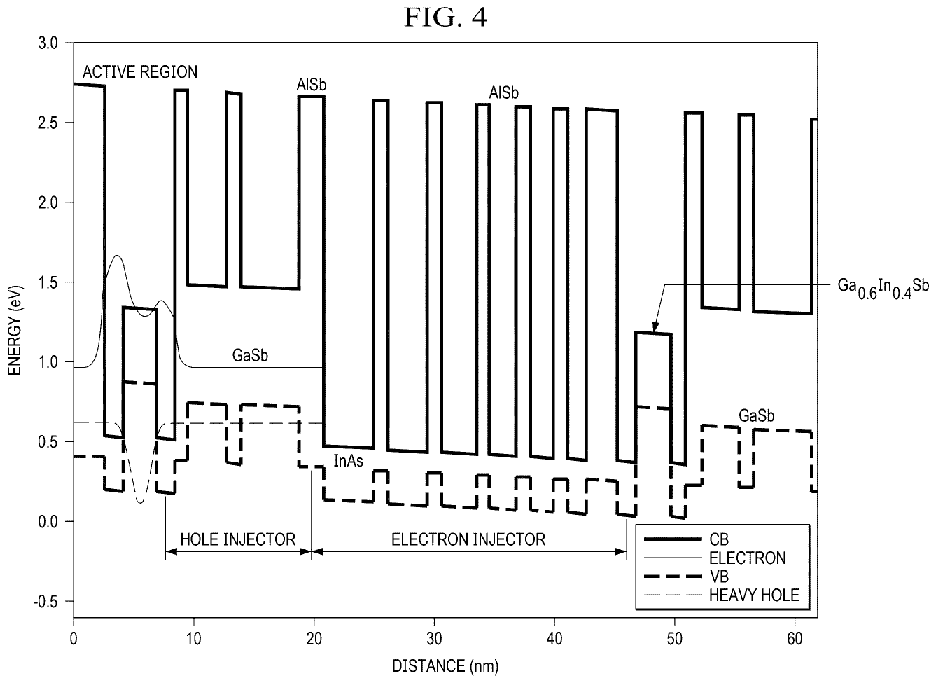

In a non-limiting example, the interband cascade region 12 in FIG. 1 comprises 6 interband cascade stages, each stage of which comprises a GaSb/AlSb quantum well (QW) hole injector, an InAs/AlSb electron injector, and an active region consisting of a layer sequence of AlSb/InAs/Ga_{0.6}In_{0.4}Sb/InAs/AlSb (25/16.5/28/14/12 in Å) in the growth direction as shown in FIG. 4. In a non-limiting example of an ICL, this interband cascade region is sandwiched between two 210 nm-thick lightly Te doped (2.7×10¹⁷ cm⁻³) GaSb SCLs (36 and 38 in FIG. 1) and two 0.75-μm-thick n-doped (1.5×10¹⁷ cm⁻³) InAs/AlSb inner SL cladding layers (26 and 28 in FIG. 1), and then wrapped by 1.0-μm-thick bottom and 0.75-μm-thick top n⁺-doped (3.2×10¹⁹ cm⁻³) InAs_{0.91}Sb_{0.09} layers, which are similar to 16 and 18, respectively as shown in FIG. 1. This ICL structure was grown on a GaSb substrate, from which broad-area (BA) Fabry-Perot (FP) devices were made and lasing was observed with emission wavelength near 3.6 μm at room temperature (300 K). However, the 0.75-μm-thick top n⁺-doped InAs_{0.91}Sb_{0.09} layer in this example may be too thick to etch through to form a DFB grating. Another approach is to etch this entire top n⁺-doped InAs_{0.91}Sb_{0.09} layer down to about 300 nm and then a DFB grating can be formed in this about 300-nm-thick InAs_{0.91}Sb_{0.09} layer.

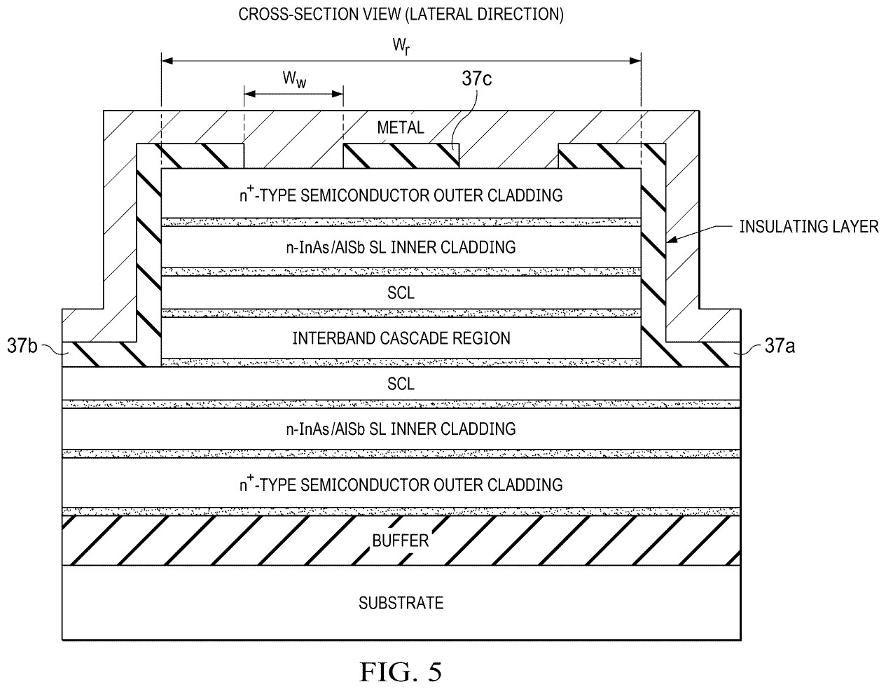

In the presently disclosed DFB ICL, compared to other ICLs with only the SL cladding that is thicker than about 1.5 μm, the disclosed inner cladding layer thickness is reduced. For example, for an ICL with a lasing wavelength near about 3.3 μm, the inner cladding layer thickness is reduced to about 0.75 μm. This will allow substantial mode coupling between the top DFB grating corrugations without the need for deep etching. This reduction in the SL cladding layer thickness also improves the thermal dissipation. The top of the ridge device with a width Wᵣ is surrounded by a layer of low index dielectric material 37 as shown in FIG. 5. A several micron-thick electroplated Au layer is employed on the top of the device for enhancing heat dissipation under cw operation. To avoid extra absorption losses from the top contact metal layer with the top cladding region, the center of the insulation layer (37c) with an appropriate thickness is kept in the middle of the ridge waveguide as shown in FIG. 5. In this way, the low index insulation layer in the middle part of the ridge serves a partial role of the top cladding layer so that the optical wave interaction with the metal layer is minimized. Current injection is realized through the metal contact pads near the edges of the top ridge, i.e., the windows with a width W_{w} between 37a and 37c and between 37b and 37c as shown in FIG. 5. The lateral carrier injection over the whole region is ensured with a large ratio between in-plane to vertical conductivity in the InAs/AlSb SL cladding region. The metal contacts near the edges of the ridge introduce some loss, which will suppress the appearance of high-order lateral modes. This metal configuration will benefit the single-mode operation with a relatively wide ridge. As a non-limiting example, the ridge width Wᵣ is in the range of 10 to 25 μm, the center dielectric insulation layer 37c has a width of 2 to 5 μm, and the window has a width of 2 to 5 μm.

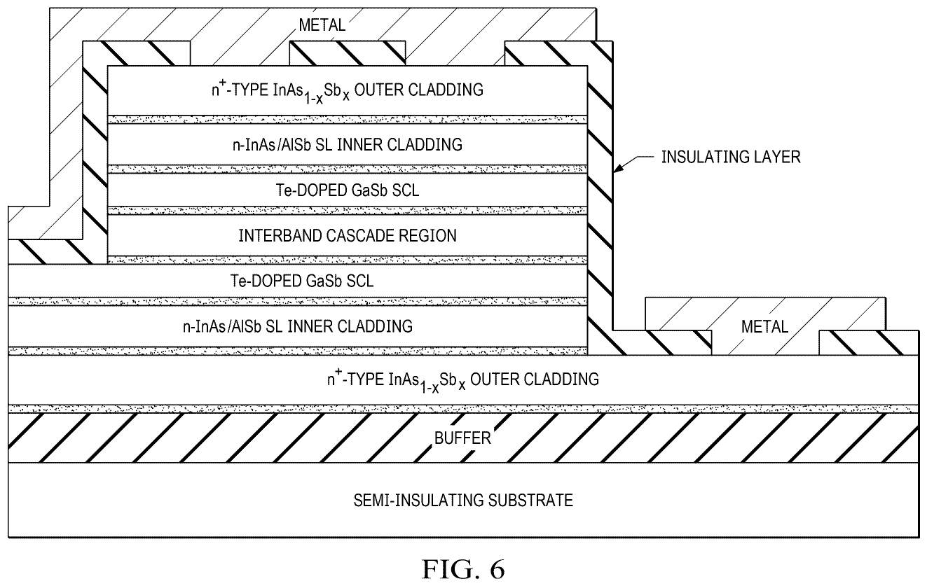

ICL structures can be grown on a semi-insulating substrate like an Si substrate. However, the semi-insulating substrate is a poor electric conductor. To make smooth electric current injection with a minimized resistance, a configuration is shown in FIG. 6, in which the bottom n⁺-InAsSb layer not only plays a role as an outer cladding layer, but also serves as a bottom metal contact layer. Due to its high electron concentration, the electric resistance is minimized, which reduces the voltage drop across the ICL device, especially with a high current.

The composition (x) of Sb in InAsSb is chosen so that the lattice constant of InAsSb is approximately matched to the lattice constant of the interband cascade region and SCL. In the example shown in FIG. 6, x is chosen to match the lattice constant of GaSb. If the cascade region is lattice matched to InAs with the InAs as the SCL, the Sb composition (x) for InAs₁₋ₓSbₓ is zero. A high doped n⁺-InAs layer will be used for the outer cladding and metal contact layer.

A buffer layer, such as shown in FIG. 1 and FIG. 6, can be used to accommodate possible lattice mismatch between the substrate and subsequent layers or/and to improve adhesion. In some scenarios, the substrate may not be semi-insulating, but for certain other applications, top metal contacts are required instead of the substrate-backside metal contact. Metals that can be used to construct the metal contacts of the present disclosure include any suitable metal known to those of ordinary skill in the art for such devices, and particularly include, but are not limited to, gold, silver, titanium, n copper, platinum, palladium, and alloys thereof.

The present disclosure is directed to, in at least a certain embodiment, a semiconductor DFB IC laser comprising (1) an IC region having an IC region real refractive index, the IC region configured to generate light based on interband transitions, wherein the interband transitions define an energy range of emitted photons and a corresponding lasing wavelength spectrum; (2) an inner cladding layer positioned adjacent to the IC region, the inner cladding layer comprising an inner cladding layer semiconductor material and having an inner cladding layer real refractive index which is lower than the IC region real refractive index; (3) an outer cladding layer positioned adjacent to the inner cladding layer, the outer cladding layer comprising a high-doped n⁺-type semiconductor material and having an outer cladding layer real refractive index which is lower than the IC region real refractive index; and (4) a DFB grating in the outer cladding layer, wherein the DFB grating is configured to select a single mode emission. The semiconductor DFB IC laser may further comprise (a) a ridge based on etching through the cladding layers and IC region, comprising a ridge top and edges, and having a width of about 10-25 μm; (b) a dielectric insulation layer covering the ridge and comprising two windows and a dielectric insulation layer top, wherein the two windows have a width of about 2-5 μm near the edges so that a center of the ridge top is covered with the dielectric insulation layer with a width of about 2-5 μm; and (c) a metal layer covering the dielectric insulation layer top and the windows, wherein the metal layer is connected to the outer cladding layer through the two windows. The high-doped n⁺-type semiconductor material may comprise a doping concentration in a range of about 5×10¹⁷ cm⁻³ to about 5×10¹⁹ cm⁻³. The laser may further comprise at least one SCL positioned between the IC region and the inner cladding layer, wherein the at least one SCL comprises an SCL semiconductor material having an SCL real refractive index which is greater than the inner cladding layer real refractive index. The SCL real refractive index may be greater than the IC region real refractive index. The SCL semiconductor material may be selected from the group consisting of InAs, InGaAsSb, GaSb, AlGaInSb, AlGaSbAs, and AlGaInSbAs. The inner cladding layer may be selected from the group consisting of a superlattice layer, a ternary semiconductor material, and a quaternary semiconductor material. The inner cladding layer may be made of a short period of an InAs/AlSb superlattice layer. The DFB grating may comprise a dielectric material selected from the group consisting of Si₃N₄ and SiO₂.

The present disclosure is further directed to, in at least another embodiment, a semiconductor DFB IC laser comprising (1) an IC region having an IC region real refractive index, the IC region configured to generate light based on interband transitions, wherein the interband transitions define an energy range of emitted photons and a corresponding lasing wavelength spectrum; (2) a first outer cladding layer positioned above the IC region, wherein the first outer cladding layer comprises a first outer cladding layer high-doped n⁺-type semiconductor material and has a first outer cladding layer real refractive index which is less than the IC region real refractive index; (3) a first inner cladding layer positioned between the IC region and the first outer cladding layer, wherein the first inner cladding layer comprises a first inner cladding layer semiconductor material and has a first inner cladding layer real refractive index which is less than the IC region real refractive index; (4) a second outer cladding layer positioned below the IC region, wherein the second outer cladding layer comprises a second outer cladding layer high-doped n⁺-type semiconductor material and has a second outer cladding layer real refractive index which is less than the IC region real refractive index; (5) a second inner cladding layer positioned between the IC region and the second outer cladding layer, wherein the second inner cladding layer comprises a second inner cladding layer semiconductor material and has a second inner cladding layer real refractive index which is less than the IC region real refractive index; and (6) a DFB grating in the first outer cladding layer, wherein the DFB grating is configured to select a single mode emission. The laser may further comprise (a) a ridge based on etching through the first cladding layers and IC region, comprising a ridge top and edges, and having a width of about 10-μm; (b) a dielectric insulation layer covering the ridge and comprising two windows and a dielectric insulation layer top, wherein the two windows have a width of about 2-5 μm near the edges so that a center of the ridge top is covered with the dielectric insulation layer with a width of about 2-5 μm; and (c) a metal layer covering the dielectric insulation layer top and the windows, wherein the metal layer is connected to the first outer cladding layer through the two windows. The first outer cladding layer high-doped n⁺-type semiconductor material and the second outer cladding layer high-doped n⁺-type semiconductor material may comprise a doping concentration in a range of about 5×10¹⁷ cm⁻³ to about 5×10¹⁹ cm⁻³. The laser may further comprise (a) a first SCL positioned between the IC region and the first inner cladding layer, comprising a first SCL semiconductor material, and having a first SCL real refractive index which is greater than the first inner cladding layer real refractive index; and (b) a second SCL positioned between the IC region and the second inner cladding layer, comprising a second SCL semiconductor material, and having a second SCL real refractive index which is greater than the second inner cladding layer real refractive index. The first SCL real refractive index and the second SCL refractive index may be greater than the IC region real refractive index. The first SCL semiconductor material and the second SCL semiconductor material may be independently selected from the group consisting of InAs, InGaAsSb, GaSb, AlGaInSb, AlGaSbAs, and AlGaInSbAs. The first inner cladding layer semiconductor material and the second inner cladding layer semiconductor material may be independently selected from the group consisting of a superlattice layer, a ternary semiconductor material, and a quaternary semiconductor material. The first inner cladding layer and the second inner cladding layer may be made of a short period of an InAs/AlSb superlattice layer. The DFB grating may comprise a dielectric material selected from the group consisting of Si₃N₄ and SiO₂. The laser may further comprise a metal contact connected to the first outer cladding layer.

The present disclosure is directed to, in at least another embodiment, a semiconductor DFB IC laser comprising (1) an IC region having an IC region real refractive index, the IC region configured to generate light based on interband transitions, wherein the interband transitions define an energy range of emitted photons and a corresponding lasing wavelength spectrum; (2) a first outer cladding layer positioned above the IC region, wherein the first outer cladding layer comprises a first outer cladding layer high-doped n⁺-type semiconductor material and has a first outer cladding layer real refractive index which is less than the IC region real refractive index; (3) a first inner cladding layer positioned between the IC region and the first outer cladding layer, wherein the first inner cladding layer comprises a first inner cladding layer semiconductor material and has a first inner cladding layer real refractive index which is less than the IC region real refractive index; (4) a second outer cladding layer positioned below the IC region, wherein the second outer cladding layer comprises a second outer cladding layer high-doped n⁺-type semiconductor material and has a second outer cladding layer real refractive index which is less than the IC region real refractive index; (5) a second inner cladding layer positioned between the IC region and the second outer cladding layer, wherein the second inner cladding layer comprises a second inner cladding layer semiconductor material and has a second inner cladding layer real refractive index which is less than the IC region real refractive index; and (a) a DFB grating in the first outer cladding layer, wherein the DFB grating is configured to select a single mode emission; (b) a first metal contact connected to the first outer cladding layer; (c) a substrate positioned below and adjacent to the second outer cladding layer; and (d) a second metal contact connected to the second outer cladding layer. The laser may further comprise (a) a ridge based on etching through the first cladding layers and IC region, comprising a ridge top and edges, and having a width of about 10-25 μm; (b) a dielectric insulation layer covering the ridge and comprising two windows and a dielectric insulation layer top, wherein the two windows have a width of about 2-5 μm near the edges so that a center of the ridge top is covered with the dielectric insulation layer with a width of about 2-5 μm; and (c) a metal layer covering the dielectric insulation layer top and the windows, wherein the metal layer is connected to the first outer cladding layer through the two windows. The first outer cladding layer high-doped n⁺-type semiconductor material and the second outer cladding layer high-doped n⁺-type semiconductor material may comprise a dopant in a concentration in a range of about 5×10¹⁷ cm⁻³ to about 5×10¹⁹ cm⁻³. The laser may further comprise (a) a first SCL positioned between the IC region and the first inner cladding layer, comprising a first SCL semiconductor material, and having a first SCL real refractive index which is greater than the first inner cladding layer real refractive index; and (b) a second SCL positioned between the IC region and the second inner cladding layer, comprising a second SCL semiconductor material, and having a second SCL real refractive index greater than the second inner cladding layer real refractive index. The first SCL semiconductor material and the second SCL semiconductor material may be independently selected from the group consisting of InAs, InGaAsSb, GaSb, AlGaInSb, AlGaSbAs, and AlGaInSbAs. The first inner cladding layer semiconductor material and the second inner cladding layer semiconductor material may be independently selected from the group consisting of a superlattice layer, a ternary semiconductor material, and a quaternary semiconductor material. The DFB grating may comprise a dielectric material selected from the group consisting of Si₃N₄ and SiO₂. The substrate may be a semi-insulating substrate selected from the group consisting of GaAs, Si, and InP The first outer cladding layer high-doped semiconductor material and the second outer cladding layer high-doped semiconductor material may comprise a semiconductor material selected from the group consisting of n⁺-type InAsSb and n⁺-type InAs.

While the present disclosure has been described in connection with certain embodiments so that aspects thereof may be more fully understood and appreciated, it is not intended that the present disclosure be limited to these particular embodiments. On the contrary, it is intended that all alternatives, modifications and equivalents are included within the scope of the present disclosure. Thus the examples described above, which include particular embodiments, will serve to illustrate the practice of the present disclosure, it being understood that the particulars shown are by way of example and for purposes of illustrative discussion of particular embodiments only and are presented in the cause of providing what is believed to be the most useful and readily understood description of procedures as well as of the principles and conceptual aspects of the presently disclosed methods and compositions. Changes may be made in the compositions and structures of the various components described herein, or the methods described herein without departing from the spirit and scope of the present disclosure.

What is claimed is:

1. A semiconductor distributed feedback (DFB) interband cascade (IC) laser comprising:
an IC region having an IC region real refractive index, the IC region configured to generate light based on interband transitions, wherein the interband transitions define an energy range of emitted photons and a corresponding lasing wavelength spectrum;
an inner cladding layer positioned adjacent to the IC region, the inner cladding layer comprising an inner cladding layer semiconductor material and having an inner cladding layer real refractive index which is lower than the IC region real refractive index;
an outer cladding layer positioned adjacent to the inner cladding layer, the outer cladding layer comprising a high-doped n⁺-type semiconductor material and having an outer cladding layer real refractive index which is lower than the IC region real refractive index; and
a DFB grating in the outer cladding layer, the DFB grating configured to select a single mode emission.

2. The semiconductor DFB IC laser of claim 1, further comprising:
a ridge based on etching through the cladding layers and IC region, comprising a ridge top and edges, and having a width of about 10-25 micrometers (μm);
a dielectric insulation layer covering the ridge and comprising two windows and a dielectric insulation layer top, wherein the two windows have a width of about 2-5 μm near the edges so that a center of the ridge top is covered with the dielectric insulation layer with a width of about 2-5 μm; and
a metal layer covering the dielectric insulation layer top and the windows, wherein the metal layer is connected to the outer cladding layer through the two windows.

3. The semiconductor DFB IC laser of claim 1, wherein the high-doped n⁺-type semiconductor material comprises a doping concentration in a range of about 5×10¹⁷ inverse cubic centimeters (cm⁻³) to about 5×10¹⁹ cm⁻³.

4. The semiconductor DFB IC laser of claim 1, further comprising at least one separate confinement layer (SCL) positioned between the IC region and the inner cladding layer, wherein the at least one SCL comprises an SCL semiconductor material having an SCL real refractive index which is greater than the inner cladding layer real refractive index.

5. The semiconductor DFB IC laser of claim 4, wherein the SCL real refractive index is greater than the IC region real refractive index.

6. The semiconductor DFB IC laser of claim 4, wherein the SCL semiconductor material is selected from the group consisting of indium arsenide (InAs), indium gallium arsenic antimonide (InGaAsSb), gallium antimonide (GaSb), aluminum gallium indium antimonide (AlGaInSb), aluminum gallium antimony arsenide (AlGaSbAs), and aluminum gallium indium antimony arsenide (AlGaInSbAs).

7. The semiconductor DFB IC laser of claim 1, wherein the inner cladding layer is selected from the group consisting of a superlattice layer, a ternary semiconductor material, and a quaternary semiconductor material.

8. The semiconductor DFB IC laser of claim 7, wherein the inner cladding layer is made of a short period of an indium arsenide (InAs)/aluminum antimonide (AlSb) superlattice layer.

9. The semiconductor DFB IC laser of claim 1, wherein the DFB grating comprises a dielectric material selected from the group consisting of silicon nitride (Si₃N₄) and silicon dioxide (SiO₂).

10. A semiconductor distributed feedback (DFB) interband cascade (IC) laser comprising:
an IC region having an IC region real refractive index, the IC region configured to generate light based on interband transitions, wherein the interband transitions define an energy range of emitted photons and a corresponding lasing wavelength spectrum;
a first outer cladding layer positioned above the IC region, wherein the first outer cladding layer comprises a first outer cladding layer high-doped n⁺-type semiconductor material and has a first outer cladding layer real refractive index which is less than the IC region real refractive index;
a first inner cladding layer positioned between the IC region and the first outer cladding layer, wherein the first inner cladding layer comprises a first inner cladding layer semiconductor material and has a first inner cladding layer real refractive index which is less than the IC region real refractive index;
a second outer cladding layer positioned below the IC region, wherein the second outer cladding layer comprises a second outer cladding layer high-doped n⁺-type semiconductor material and has a second outer cladding layer real refractive index which is less than the IC region real refractive index;
a second inner cladding layer positioned between the IC region and the second outer cladding layer, wherein the second inner cladding layer comprises a second inner cladding layer semiconductor material and has a second inner cladding layer real refractive index which is less than the IC region real refractive index; and
a DFB grating in the first outer cladding layer, wherein the DFB grating is configured to select a single mode emission.

11. The semiconductor DFB IC laser of claim 10, further comprising:
a ridge based on etching through the first cladding layers and IC region, comprising a ridge top and edges, and having a width of about 10-25 micrometers (μm);
a dielectric insulation layer covering the ridge and comprising two windows and a dielectric insulation layer top, wherein the two windows have a width of about 2-5 μm near the edges so that a center of the ridge top is covered with the dielectric insulation layer with a width of about 2-5 μm; and
a metal layer covering the dielectric insulation layer top and the windows, wherein the metal layer is connected to the first outer cladding layer through the two windows.

12. The semiconductor DFB IC laser of claim 10, wherein the first outer cladding layer high-doped n⁺-type semiconductor material and the second outer cladding layer high-doped n⁺-type semiconductor material comprise a doping concentration in a range of about 5×10¹⁷ inverse cubic centimeters (cm⁻³) to about 5×10¹⁹ cm⁻³.

13. The semiconductor DFB IC laser of claim 10, further comprising:
a first separate confinement layer (SCL) positioned between the IC region and the first inner cladding layer, comprising a first SCL semiconductor material, and having a first SCL real refractive index which is greater than the first inner cladding layer real refractive index; and
a second SCL positioned between the IC region and the second inner cladding layer, comprising a second SCL semiconductor material, and having a second SCL real refractive index which is greater than the second inner cladding layer real refractive index.

14. The semiconductor DFB IC laser of claim 13, wherein the first SCL real refractive index and the second SCL refractive index are greater than the IC region real refractive index.

15. The semiconductor DFB IC laser of claim 13, wherein the first SCL semiconductor material and the second SCL semiconductor material are independently selected from the group consisting of indium arsenide (InAs), indium gallium arsenic antimonide (InGaAsSb), gallium antimonide (GaSb), aluminum gallium indium antimonide (AlGaInSb), aluminum gallium antimony arsenide (AlGaSbAs), and aluminum gallium indium antimony arsenide (AlGaInSbAs).

16. The semiconductor DFB IC laser of claim 10, wherein the first inner cladding layer semiconductor material and the second inner cladding layer semiconductor material are independently selected from the group consisting of a superlattice layer, a ternary semiconductor material, and a quaternary semiconductor material.

17. The semiconductor DFB IC laser of claim 16, wherein the first inner cladding layer and the second inner cladding layer are made of a short period of an indium arsenide (InAs)/aluminum antimonide (AlSb) superlattice layer.

18. The semiconductor DFB IC laser of claim 10, wherein the DFB grating comprises a dielectric material selected from the group consisting of silicon nitride (Si₃N₄) and silicon dioxide (SiO₂).

19. The semiconductor IC laser of claim 10, further comprising a metal contact connected to the first outer cladding layer.

20. A semiconductor distributed feedback (DFB) interband cascade (IC) laser comprising:
an IC region having an IC region real refractive index, the IC region configured to generate light based on interband transitions, wherein the interband transitions define an energy range of emitted photons and a corresponding lasing wavelength spectrum;
a first outer cladding layer positioned above the IC region, wherein the first outer cladding layer comprises a first outer cladding layer high-doped n⁺-type semiconductor material and has a first outer cladding layer real refractive index which is less than the IC region real refractive index;
a first inner cladding layer positioned between the IC region and the first outer cladding layer, wherein the first inner cladding layer comprises a first inner cladding layer semiconductor material and has a first inner cladding layer real refractive index which is less than the IC region real refractive index;
a second outer cladding layer positioned below the IC region, wherein the second outer cladding layer comprises a second outer cladding layer high-doped n⁺-type semiconductor material and has a second outer cladding layer real refractive index which is less than the IC region real refractive index;
a second inner cladding layer positioned between the IC region and the second outer cladding layer, wherein the second inner cladding layer comprises a second inner cladding layer semiconductor material and has a second inner cladding layer real refractive index which is less than the IC region real refractive index; and
a DFB grating in the first outer cladding layer, wherein the DFB grating is configured to select a single mode emission;
a first metal contact connected to the first outer cladding layer;
a substrate positioned below and adjacent to the second outer cladding layer; and
a second metal contact connected to the second outer cladding layer.
